(19) United States
(12) Patent Application Publication
(10) Pub. No.: US 2026/0299413 A1
(43) Pub. Date: Oct. 1, 2026

(54) PHOTORESIST FILM

(71) Applicant: DUPONT ELECTRONICS, INC., Wilmington, DE (US)

(72) Inventors: HUNG-TE CHENG, HSINCHU (TW); YI-TING CHEN, HSINCHU (TW); TSUNG-HAN TSAI, HSINCHU (TW); CHARNG-YU LIN, HSINCHU (TW); LIYEN LIN, HSINCHU (TW)

(21) Appl. No.: 19/572,826

(22) Filed: Mar. 19, 2026

Related U.S. Application Data
(60) Provisional application No. 63/777,311, filed on Mar. 25, 2025.

(51) Int. Cl. G03F 7/032; G03F 7/031

(52) U.S. Cl. CPC G03F 7/032; G03F 7/031

(57) ABSTRACT

The present disclosure provides a photoresist film. The photoresist film is formed from a photosensitive composition comprising a polymeric binder which comprises a first structural unit derived from a (meth)acrylate compound with an epoxy group, a polymerizable compound, and a photoinitiator. The photoresist film has excellent lithographic performance and is particularly suitable for 2.5D and 3D integrated circuits packaging.

### FIELD OF THE INVENTION

The present disclosure provides a photoresist film. The photoresist film of the present disclosure has excellent lithographic performance and is particularly suitable for 2.5D and 3D integrated circuits packaging.

### BACKGROUND

In the fields of printed circuit boards (PCBs) and integrated circuits (ICs), photoresist films are known to be used for forming circuit patterns through etching or electroplating processes. The general process for forming circuit patterns typically comprises performing lithographic processes, including exposure and development processes, on a photoresist film to form a resist pattern and then performing etching or electroplating processes to form a circuit pattern. After the etching or plating processes, the cured photoresist film/resist pattern is generally stripped from the substrate.

With the development trend of electronic and communication products, there are increasing demands for higher wiring/packing density and precise patterning. To ensure patterns with high precision, photoresist films are required to have satisfactory lithographic performance. Some lithographic properties of particular concern include stripping residue and footing.

Conventional methods for reducing stripping residue include increasing the acid content or hydrophilicity of the photoresist or decreasing monomer crosslinking density. However, these approaches may result in severe via distortion and/or concave defect on the film surface.

Conventional methods for reducing footing include increasing monomer crosslinking density. However, this may sacrifice the efficiency in reducing stripping residue.

Therefore, there is an ongoing need for new photoresists having good lithographic performance, particularly in terms of stripping residue and footing.

### SUMMARY

In view of the aforementioned technical problems, the present disclosure provides a photoresist film. The photoresist film of the present disclosure has excellent lithographic performance, particularly in terms of stripping residue and footing. In some embodiments of the present disclosure, the photoresist film further has comparably better photosensitivity and may shorten the exposure time required in the lithographic process.

Accordingly, an objective of the present disclosure is to provide a photoresist film, which is formed from a photosensitive composition comprising:
(A) a polymeric binder, which comprises a first structural unit derived from a (meth)acrylate compound with an epoxy group;
(B) a polymerizable compound; and
(C) a photoinitiator.

In an embodiment of the present disclosure, the (meth)acrylate compound with an epoxy group is selected from the group consisting of glycidyl(meth)acrylate, 2-methylglycidyl(meth)acrylate, epoxybutyl(meth)acrylate, epoxypentyl(meth)acrylate, epoxyhexyl(meth)acrylate, epoxyheptyl(meth)acrylate, epoxycyclohexylmethyl(meth)acrylate, gastrodigenin epoxy (meth)acrylate, tyrosol epoxy (meth)acrylate, and combinations thereof.

In an embodiment of the present disclosure, the polymeric binder (A) further comprises a second structural unit derived from the group consisting of a (meth)acrylate compound without an epoxy group, a (meth)acrylic acid compound, an aromatic vinyl compound, a maleate compound, a linear aliphatic vinyl compound, a cycloaliphatic vinyl compound, and combinations thereof.

In an embodiment of the present disclosure, the (meth)acrylate compound without an epoxy group is selected from the group consisting of benzyl(meth)acrylate, methyl(meth)acrylate, n-propyl(meth)acrylate, isopropyl(meth)acrylate, n-butyl(meth)acrylate, isobutyl(meth)acrylate, 2-ethylhexyl(meth)acrylate, tert-butyl(meth)acrylate, 2-hydroxyethyl(meth)acrylate, 2-hydroxypropyl(meth)acrylate, cyclohexyl(meth)acrylate, 1-methyl-cyclopentyl(meth)acrylate, 1-methyl-cyclohexyl(meth)acrylate, adamantyloxyethyl(meth)acrylate, 2-methyl-2-adamantyl(meth)acrylate, 2-ethyl-2-adamantyl(meth)acrylate, 2-butyl-2-adamantyl(meth)acrylate, furfuryl(meth)acrylate, tetrahydrofurfuryl(meth)acrylate, dimethylamino ethyl(meth)acrylate, diethylamino ethyl(meth)acrylate, 2,2,2-trifluoroethyl(meth)acrylate, 2,2,3,3-tetrafluoropropyl(meth)acrylate, isobornyl(meth)acrylate, isobonyloxyethyl(meth)acrylate, dicyclopentanyl(meth)acrylate, dimethylaminoethyl(meth)acrylate, diethylaminoethyl(meth)acrylate, dicyclopentenyl-oxyethyl(meth)acrylate, dicyclopentanyl-oxyethyl(meth)acrylate, cyclohexyloxyethyl(meth)acrylate, dicyclopentenyloxypropyloxyethyl(meth)acrylate, and combinations thereof.

In an embodiment of the present disclosure, the (meth)acrylic acid compound is selected from the group consisting of (meth)acrylic acid, α-bromo(meth)acrylic acid, α-chloro(meth)acrylic acid, β-phthalimido(meth)acrylic acid, β-styryl(meth)acrylic acid, β-furyl(meth)acrylic acid, and combinations thereof.

In an embodiment of the present disclosure, the aromatic vinyl compound is selected from the group consisting of styrene, α-methyl styrene, vinyl naphthalene, 3-acetoxystyrene, 4-acetoxystyrene, vinyl toluene, and combinations thereof.

In an embodiment of the present disclosure, the polymerizable compound (B) is selected from the group consisting of t-butyl(meth)acrylate, cyclohexyl(meth)acrylate, ethylene glycol di(meth)acrylate, butanediol di(meth)acrylate, hexamethylene glycol di(meth)acrylate, diethylene glycol di(meth)acrylate, tripropylene glycol di(meth)acrylate, 1,4-cyclo-hexanediol di(meth)acrylate, 2,2-dimethylolpropane di(meth)acrylate, polyethylene glycol di(meth)acrylate, polypropylene glycol di(meth)acrylate, trimethylolpropane di(meth)acrylate, glycerol di(meth)acrylate, glycerol tri(meth)acrylate, trimethylolpropane tri(meth)acrylate, ethoxylated trimethylolpropane tri(meth)acrylate, triethylene glycol di(meth)acrylate, ethoxylated bisphenol A di(meth)acrylate, propoxylated propylene glycol mono(meth)acrylate, propoxylated propylene glycol di(meth)acrylate, pentaaerythritol tri(meth)acrylate, pentaaerythritol tetra(meth)acrylate, 2,2-bis(4-((meth)-acryloxypolyethoxy)phenyl) propane, 2,2-bis(4-((meth)acryloxypolypropoxy)phenyl) propane, 2,2-bis(4-((meth)acryloxypolybutoxy)phenyl) propane, 2,2-bis(4-((meth)acryloxy-polyethoxypolypropoxy)phenyl) propane, and combinations thereof.

In an embodiment of the present disclosure, the photoinitiator (C) is selected from the group consisting of benzophenone, bis-4,4′-dimethylaminobenzo-phenone, bis-4,4′-diethyl-aminobenzo-phenone, 2-benzyl-2-dimethylamino-1-(4-morpholino-phenyl)-1-butanone, 2-methyl-1-[4-(methylthio)phenyl]-2-morpholino-1-propanone, 9,10-anthroquinones, 1,4-naphthquinones, phenanthrene quinones, N-Phenylglycine, benzoin, benzyl dimethyl ketal, 2,2′-bis(2-chlorophenyl)-4,4′,5,5′-tetraphenylbiimidazole, 2,2′,5-tris(o-chlorophenyl)-4-(3,4-di-methoxyphenyl)-4′,5′-diphenyl-1,l′-biimidazole, 2,2′4,4′-tetra(o-chloro-phenyl)-5,5′-bis(3,4-dimethoxyphenyl)-1,1′-biimidazole, 2,2′-bis(o-chloro-phenyl)-4,4′,5,5′-tetra(m-methoxyphenyl)-1,l′-biimidazole, and 2,2′-bis(2-ethoxyphenyl)-4,4′,5,5′-tetraphenyl-1,1′-biimidazole, 9-phenylacridine, 1,7-(9,9′-acridinyl) heptane, and combinations thereof.

In an embodiment of the present disclosure, the photosensitive composition further comprises an additive selected from the group consisting of a photosensitizer, an adhesion modifier, an inhibitor, a light absorber, a dye, a pigment, a surfactant, an antioxidant, a solvent, and combinations thereof.

In an embodiment of the present disclosure, the polymeric binder (A) is comprised in a solution comprising an inhibitor, and the amount of the inhibitor is 300 ppm or less relative to 100 parts by weight of the polymeric binder (A).

In an embodiment of the present disclosure, the inhibitor comprises hydroquinone, methylhydroquinone, tert-butylhydroquinone, 2,5-di-tert-butylhydroquinone, 2,5-bis(1,1-dimethylbutyl) hydroquinone, 2,5-bis(1,1,3,3-tetramethylbutyl) hydroquinone, resorcin, catechol, 4-tert-butylcatechol, hymono-methyl ether hydroquinone (MEHQ), pyrogallol, butylated hydroxytoluene, 2-naphthol, or a combination thereof.

In an embodiment of the present disclosure, the photoresist film has a thickness ranging from 1 μm to 600 μm.

To render the above objectives, technical features, and advantages of the present disclosure more apparent, the present disclosure will be described in detail with reference to some embodiments hereinafter.

### DETAILED DESCRIPTION

Hereinafter, some embodiments of the present disclosure will be described in detail. However, the present disclosure may be embodied in various embodiments, and the protection scope of the present disclosure should not be limited to those described in the specification.

As used herein, the expressions “a”, “the”, or the like recited in the specification and in the claims should include both the singular and the plural forms unless stated otherwise.

As used herein, the terms “first”, “second”, or the like recited in the specification and in the claims are only used to distinguish the illustrated elements or components and do not represent any priority.

As used herein, the term “(meth)acrylate” intends to include both acrylate and methacrylate. Similarly, the term “(meth)acrylic acid” intends to include both acrylic acid and methacrylic acid.

In comparison to prior art, the present disclosure provides a photoresist film having superior lithographic performance, such as less stripping residue, shorter footing, and/or higher photosensitivity by using specific components in the photosensitive composition forming the photoresist. The photoresist film of the present disclosure is described in detail below

### Photoresist Film

Photoresist films refer to a group of film materials that undergo chemical reaction upon light exposure. Based on their structural changes after exposure and development, photoresist films can be categorized into positive photoresist films and negative photoresist films. In an embodiment of the present disclosure, the photoresist film of the present disclosure is a negative photoresist film. That is, after the photoresist film is exposed, the portion not exposed to light will be dissolved during development, and the exposed portion will remain after development.

In an embodiment of the present disclosure, the photoresist film of the present disclosure is a dry film. The term “dry film” refers to a film that contains essentially no solvent or only trace amount of solvent, such as less than 5 wt % based on the total weight of the photoresist film. In comparison to ink-like or liquid-like wet films, dry films are less likely to flow or deform due to their low solvent content, and can be attached to a substrate without additional treatment or steps, so they are beneficial for processing. Typical methods for forming a dry film comprises coating a photosensitive composition onto a substrate and subjecting it to drying process to remove solvent, thereby obtaining a dry film with desired thickness.

The photoresist film of the present disclosure has a thickness ranging from 1 μm to 600 μm, preferably 100 μm to 600 μm, more preferably 200 μm to 600 μm. For example, the thickness of the photoresist film of the present disclosure can be 1 μm, 5 μm, 10 μm, 50 μm, 100 μm, 150 μm, 200 μm, 220 μm, 240 μm, 250 μm, 260 μm, 280 μm, 300 μm, 320 μm, 340 μm, 350 μm, 360 μm, 380 μm, 400 μm, 420 μm, 440 μm, 450 μm, 460 μm, 480 μm, 500 μm, 520 μm, 540 μm, 550 μm, 560 μm, 580 μm, or 600 μm, or within a range between any two of the values described herein. A higher thickness implies more space can be utilized for structural design and may be desirable.

The photoresist film of the present disclosure can be prepared from a specific photosensitive composition, which is described below.

### Photosensitive Composition

In the present disclosure, the photosensitive composition comprises (A) a polymeric binder, (B) a polymerizable compound and (C) a photoinitiator as essential components and may further comprise optional components. The components are described in detail below.

### (A) Polymeric Binder

In the present disclosure, the polymeric binder comprises a first structural unit derived from a (meth)acrylate compound with an epoxy group as an essential component. The inventor surprisingly found that by incorporating the first structural unit derived from a (meth)acrylate compound with an epoxy group in the polymeric binder, the photoresist formed from the photosensitive composition would have less stripping residue and shorter footing in the lithographic process.

Examples of the (meth)acrylate compound with an epoxy group include but are not limited to glycidyl(meth)acrylate, 2-methylglycidyl(meth)acrylate, epoxybutyl(meth)acrylate, epoxypentyl(meth)acrylate, epoxyhexyl(meth)acrylate, epoxyheptyl(meth)acrylate, epoxycyclohexylmethyl(meth)acrylate, gastrodigenin epoxy (meth)acrylate, and tyrosol epoxy (meth)acrylate. The aforementioned compounds can be used alone or in combination.

In an embodiment of the present disclosure, the polymeric binder may further comprise a second structural unit different from the first structural unit. In case that the polymeric binder comprises the first structural unit and one or more second structural units, the amount of the first structural unit can be 0.3 wt % or more, particularly 0.5 wt % to 30 wt %, more particularly 0.8 wt % to 15 wt %, based on the total weight of the polymeric binder. For example, based on the total weight of the polymeric binder, the amount of the first structural unit can be 0.3 wt %, 0.4 wt %, 0.5 wt %, 0.6 wt %, 0.7 wt %, 0.8 wt %, 0.9 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, 10 wt %, 12 wt %, 14 wt %, 15 wt %, 16 wt %, 18 wt %, 20 wt %, 22 wt %, 24 wt %, 25 wt %, 26 wt %, 28 wt %, or 30 wt %, or within a range between any two of the values described herein. In one embodiment of the present disclosure, the polymeric binder comprises a main chain comprising one or more second structural units and graft chains comprising a first structural unit.

The type of the second structural unit is not particularly limited and can be derived from a variety of polymerizable compounds. In an embodiment of the present disclosure, the second structural unit may be derived from the group consisting of a (meth)acrylate compound without an epoxy group, a (meth)acrylic acid compound, an aromatic vinyl compound, a maleate compound, a linear aliphatic vinyl compound, a cycloaliphatic vinyl compound, and combinations thereof.

Specific examples of the (meth)acrylate compound without an epoxy group include but are not limited to benzyl(meth)acrylate, methyl(meth)acrylate, n-propyl(meth)acrylate, isopropyl(meth)acrylate, n-butyl(meth)acrylate, isobutyl(meth)acrylate, 2-ethylhexyl(meth)acrylate, tert-butyl(meth)acrylate, 2-hydroxyethyl(meth)acrylate, 2-hydroxypropyl(meth)acrylate, cyclohexyl(meth)acrylate, 1-methyl-cyclopentyl(meth)acrylate, 1-methyl-cyclohexyl(meth)acrylate, adamantyloxyethyl(meth)acrylate, 2-methyl-2-adamantyl(meth)acrylate, 2-ethyl-2-adamantyl(meth)acrylate, 2-butyl-2-adamantyl(meth)acrylate, furfuryl(meth)acrylate, tetrahydrofurfuryl(meth)acrylate, dimethylamino ethyl(meth)acrylate, diethylamino ethyl(meth)acrylate, 2,2,2-trifluoroethyl(meth)acrylate, 2,2,3,3-tetrafluoropropyl(meth)acrylate, isobornyl(meth)acrylate, isobonyloxyethyl(meth)acrylate, dicyclopentanyl(meth)acrylate, dimethylaminoethyl(meth)acrylate, diethylaminoethyl(meth)acrylate, dicyclopentenyl-oxyethyl(meth)acrylate, dicyclopentanyl-oxyethyl(meth)acrylate, cyclohexyloxyethyl(meth)acrylate, and dicyclopentenyloxypropyloxyethyl (meth)acrylate. The aforementioned compounds can be used alone or in combination.

Specific examples of the (meth)acrylic acid compound include but are not limited to(meth)acrylic acid, α-bromo(meth)acrylic acid, α-chloro(meth)acrylic acid, β-phthalimido(meth)acrylic acid, B-styryl(meth)acrylic acid, and β-furyl(meth)acrylic acid. The aforementioned compounds can be used alone or in combination.

Specific examples of the aromatic vinyl compound include but are not limited to styrene, α-methyl styrene, vinyl naphthalene, 3-acetoxystyrene, 4-acetoxystyrene, and vinyl toluene. The aforementioned compounds can be used alone or in combination.

Specific examples of the maleate compound include but are not limited to monomethyl maleate, monoethyl maleate, and monoisopropyl maleate. The aforementioned compounds can be used alone or in combination.

In the present disclosure, the molecular weight and polydispersity index (PDI) of the polymeric binder is not particularly limited. In an embodiment of the present disclosure, the weight average molecular weight (Mw) of the polymeric binder can range from 15,000 to 150,000, particularly 25,000 to 85,000; and the polydispersity index (PDI) of the polymeric binder can range from 1.2 to 4, particularly 1.5 to 3. The weight average molecular weight (Mw) can be determined by gel permeation chromatography (GPC) with reference to standard materials such as polystyrene.

In the present disclosure, based on the total weight of the photosensitive composition excluding solvents, the amount of the polymeric binder can range from 30 wt % to 80 wt %. For example, based on the total weight of the photosensitive composition excluding solvents, the amount of the polymeric binder can be 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, or 80 wt %, or within a range between any two of the values described herein.

The polymeric binder can be prepared by radical polymerization of a (meth)acrylate compound with an epoxy group capable of forming a first structural unit, optionally with one or more compounds capable of forming second structural units. In case that a (meth)acrylate compound with an epoxy group capable of forming a first structural unit and one or more compounds capable of forming second structural units are used, the amount of the (meth)acrylate compound with an epoxy group can be 0.3 wt % or more, particularly 0.5 wt % to 30 wt %, more particularly 0.8 wt % to 15 wt %, based on the total weight of the raw materials excluding solvents used for preparing the polymeric binder. Exemplary preparation methods of the polymeric binder are provided in the Example section below.

### (B) Polymerizable Compound

The polymerizable compound is a compound containing at least one functional group that can undergo free-radical initiated polymerization and/or crosslinking. Examples of the polymerizable compound include but are not limited to t-butyl(meth)acrylate, cyclohexyl(meth)acrylate, ethylene glycol di(meth)acrylate, butanediol di(meth)acrylate, hexamethylene glycol di(meth)acrylate, diethylene glycol di(meth)acrylate, tripropylene glycol di(meth)acrylate, 1,4-cyclo-hexanediol di(meth)acrylate, 2,2-dimethylolpropane di(meth)acrylate, polyethylene glycol di(meth)acrylate, polypropylene glycol di(meth)acrylate, trimethylolpropane di(meth)acrylate, glycerol di(meth)acrylate, glycerol tri(meth)acrylate, trimethylolpropane tri(meth)acrylate, ethoxylated trimethylolpropane tri(meth)acrylate, triethylene glycol di(meth)acrylate, ethoxylated bisphenol A di(meth)acrylate, propoxylated propylene glycol mono(meth)acrylate, propoxylated propylene glycol di(meth)acrylate, pentaaerythritol tri(meth)acrylate, pentaaerythritol tetra(meth)acrylate, 2,2-bis(4-((meth)-acryloxypolyethoxy)phenyl) propane, 2,2-bis(4-((meth)acryloxypolypropoxy)phenyl) propane, 2,2-bis(4-((meth)acryloxypolybutoxy)phenyl) propane, and 2,2-bis(4-((meth)acryloxy-polyethoxypolypropoxy)phenyl) propane. The aforementioned polymerizable compounds can be used alone or in combination.

In the present disclosure, based on the total weight of the photosensitive composition excluding solvents, the amount of the polymerizable compound can range from 15 wt % to 45 wt %. For example, based on the total weight of the photosensitive composition excluding solvents, the amount of the polymerizable compound can be 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, or 45 wt %, or within a range between any two of the values described herein.

### (C) Photoinitiator

The photoinintiator refers to a substance that can initiate polymerization under the action of light. Examples of the photoinintiator include but are not limited to benzophenone, bis-4,4′-dimethylaminobenzo-phenone, bis-4,4′-diethyl-aminobenzo-phenone, 2-benzyl-2-dimethylamino-1-(4-morpholino-phenyl)-1-butanone, 2-methyl-1-[4-(methylthio)phenyl]-2-morpholino-1-propanone, 9,10-anthroquinones, 1,4-naphthquinones, phenanthrene quinones, N-Phenylglycine, benzoin, benzyl dimethyl ketal, 2,2′-bis(2-chlorophenyl)-4,4′,5,5′-tetraphenylbiimidazole, 2,2′,5-tris(o-chlorophenyl)-4-(3,4-di-methoxyphenyl)-4′,5′-diphenyl-1,1′-biimidazole, 2,2′4,4′-tetra(o-chloro-phenyl)-5,5′-bis(3,4-dimethoxyphenyl)-1,1′-biimidazole, 2,2′-bis(o-chloro-phenyl)-4,4′,5,5′-tetra(m-methoxyphenyl)-1,l′-biimidazole, and 2,2′-bis(2-ethoxyphenyl)-4,4′,5,5′-tetraphenyl-1,l′-biimidazole, and 9-phenylacridine, 1,7-(9,9′-acridinyl) heptane. The aforementioned photoinitiator can be used alone or in combination.

In the present disclosure, based on the total weight of the photosensitive composition excluding solvents, the amount of the photoinitiator can range from 0.3 wt % to 3.5 wt %. For example, based on the total weight of the photosensitive composition excluding solvents, the amount of the photoinitiator can be 0.3 wt %, 0.4 wt %, 0.5 wt %, 0.6 wt %, 0.7 wt %, 0.8 wt %, 0.9 wt %, 1 wt %, 1.1 wt %, 1.2 wt %, 1.3 wt %, 1.4 wt %, 1.5 wt %, 1.6 wt %, 1.7 wt %, 1.8 wt %, 1.9 wt %, 2 wt %, 2.1 wt %, 2.2 wt %, 2.3 wt %, 2.4 wt %, 2.5 wt %, 2.6 wt %, 2.7 wt %, 2.8 wt %, 2.9 wt %, 3 wt %, 3.1 wt %, 3.2 wt %, 3.3 wt %, 3.4 wt %, or 3.5 wt %, or within a range between any two of the values described herein.

### Optional Components

The photosensitive composition may further comprise optional components to adaptively improve the physical or chemical properties of the photoresist film prepared therefrom, or to improve the processibility of the photosensitive composition. Examples of the optional components include but are not limited to additives such as photosensitizers, adhesion modifiers, inhibitors, light absorbers, dyes, pigments, surfactants, antioxidants, solvents, and any known additives used in the field. The aforementioned additives can be used alone or in combination. Hereinafter, photosensitizers, adhesion modifiers, inhibitors and solvents will be exemplified.

### [Photosensitizer]

In an embodiment of the present disclosure, the photosensitive composition further comprises a photosensitizer. The photosensitizer may extend light absorption band of the photosensitive composition, thereby enhancing the photosensitivity of the photosensitive composition. Examples of the photosensitizer include but are not limited to pyrazolines, anthracenes, coumarins, xanthones, oxazoles, benzoxazoles, thiazoles, benzothiazoles, triazoles, stilbenes, triazines, thiophenes, naphthalimide compounds, bis(p-dialkylaminobenzylidene) ketones, and arylidene aryl ketones. The aforementioned photosensitizers can be used alone or in combination.

Based on the total weight of the photosensitive composition excluding solvents, the amount of the photosensitizer can range from 0.001 wt % to 10 wt %, particularly 0.005 wt % to 5 wt %. For example, based on the total weight of the photosensitive composition excluding solvents, the amount of the photosensitizer can be 0.001 wt %, 0.002 wt %, 0.003 wt %, 0.004 wt %, 0.005 wt %, 0.006 wt %, 0.007 wt %, 0.008 wt %, 0.009 wt %, 0.01 wt %, 0.02 wt %, 0.03 wt %, 0.04 wt %, 0.05 wt %, 0.1 wt %, 0.15 wt %, 0.2 wt %, 0.3 wt %, 0.4 wt %, 0.5 wt %, 0.75 wt %, 1 wt %, 1.5 wt %, 2 wt %, 2.5 wt %, 3 wt %, 4 wt %, 5 wt %, 6 wt %, 7 wt %, 8 wt %, 9 wt %, or 10 wt %, or within a range between any two of the values described herein.

### [Adhesion Modifier]

In an embodiment of the present disclosure, the photosensitive composition further comprises an adhesion modifier to improve the adhesion of the photoresist film to the substrate. Examples of the adhesion modifier include but are not limited to benzotriazole, 5-chlorobenzotriazole, benzotriazole-5-carboxylic acid, 1-hydroxybenzotriazole, 2-mercapto-benzoxazole, 1H-1,2,4-triazole-3-thiol, 5-amino-1,3,4-thiodiazole-2-thiol, and mercapto-benzimidazole. The aforementioned adhesion modifiers can be used alone or in combination.

Based on the total weight of the photosensitive composition excluding solvents, the amount of the adhesion modifier can range from 50 ppm to 350 ppm. For example, based on the total weight of the photosensitive composition excluding solvents, the amount of the adhesion modifier can be 50 ppm, 60 ppm, 70 ppm, 80 ppm, 90 ppm, 100 ppm, 110 ppm, 120 ppm, 130 ppm, 140 ppm, 150 ppm, 160 ppm, 170 ppm, 180 ppm, 190 ppm, 200 ppm, 210 ppm, 220 ppm, 230 ppm, 240 ppm, 250 ppm, 260 ppm, 270 ppm, 280 ppm, 290 ppm, 300 ppm, 310 ppm, 320 ppm, 330 ppm, 340 ppm, or 350 ppm, or within a range between any two of the values described herein.

### [Inhibitor]

In an embodiment of the present disclosure, the photosensitive composition further comprises an inhibitor. Examples of the inhibitor include but are not limited to hydroquinone, methylhydroquinone, tert-butylhydroquinone, 2,5-di-tert-butylhydroquinone, 2,5-bis(1,1-dimethylbutyl) hydroquinone, 2,5-bis(1,1,3,3-tetramethylbutyl) hydroquinone, resorcin, catechol, 4-tert-butylcatechol, hymono-methyl ether hydroquinone (MEHQ), pyrogallol, butylated hydroxytoluene, and 2-naphthol. The aforementioned inhibitors can be used alone or in combination.

The inhibitor may be used to control the polymerization rate and/or crosslinking extent of the polymeric binder and/or photoresist film. However, it is found that the inhibitor used with the polymeric binder (A) may adversely affect the photosensitivity and thus the required exposure time of the photoresist film formed from the photosensitive composition. Therefore, in embodiments where shorter exposure time is desired, the amount of the inhibitor should not be too high. In an embodiment of the present disclosure, the polymeric binder (A) is comprised in a solution comprising an inhibitor, and the amount of the inhibitor is 300 ppm or less, or 200 ppm or less, or 100 ppm or less, relative to 100 parts by weight of the polymeric binder. For example, relative to 100 parts by weight of the polymeric binder, the amount of the inhibitor can be 1 ppm, 2 ppm, 2.5 ppm, 5 ppm, 7.5 ppm, 10 ppm, 12.5 ppm, 15 ppm, 17.5 ppm, 20 ppm, 22.5 ppm, 25 ppm, 27.5 ppm, 30 ppm, 32.5 ppm, 35 ppm, 37.5 ppm, 40 ppm, 42.5 ppm, 45 ppm, 47.5 ppm, 50 ppm, 52.5 ppm, 55 ppm, 57.5 ppm, 60 ppm, 62.5 ppm, 65 ppm, 67.5 ppm, 70 ppm, 72.5 ppm, 75 ppm, 77.5 ppm, 80 ppm, 82.5 ppm, 85 ppm, 87.5 ppm, 90 ppm, 92.5 ppm, 95 ppm, 97.5 ppm, or 100 ppm, or within a range between any two of the values described herein. Herein, the expression “the polymeric binder (A) is comprised in a solution comprising an inhibitor” means that the polymeric binder (A) can be included in a solution and the solution contains an inhibitor. This solution should not be confused with the overall photosensitive composition comprising polymeric binder (A), polymerizable compound (B) and photoinitiator (C). Besides the inhibitor used in solution with polymeric binder (A), the photosensitive composition may also comprise an additional inhibitor. In one embodiment, the polymeric binder (A) is comprised in a solution comprising hymono-methyl ether hydroquinone (MEHQ).

### [Solvent]

In an embodiment of the present disclosure, the photosensitive composition further comprises a solvent for the ease of handling. The solvent may be used to uniformly dissolve or disperse the components of the photosensitive composition, to lower the viscosity of the photosensitive composition, and/or to allow forming the photosensitive layer with a uniform thickness.

The type of the solvent is not particularly limited and can be any inert solvent that can dissolve or disperse the components of the photosensitive composition but does not react with them. Examples of the solvent include but are not limited to methanol, ethanol, propanol, butanol, tetrahydrofuran, acetone, methyl ethyl ketone, methyl acetate, ethyl acetate, methylcellosolve, ethylcellosolve, propyleneglycol monomethyl ether, toluene, and N,N-dimethylformamide. The aforementioned solvents can be used alone or in combination. The amount of the solvent is not particularly limited as long as it can sufficiently dissolve or disperse the components of the photosensitive composition. The solvent may be removed, partially or completely, in the drying process for preparing the photoresist film.

### Preparation of Photoresist Film

The photoresist film of the present disclosure can be prepared from the aforementioned photosensitive composition. Specifically, the components of the photosensitive composition, including (A) a polymeric binder, (B) a polymerizable compound, (C) a photoinitiator and additives as required, can be uniformly mixed with a stirrer and dissolved or dispersed in a solvent to form the photosensitive composition. Then, the photosensitive composition can be coated on a substrate and dried to obtain a photoresist film. In the preparation of the photoresist film, the drying conditions can be selected as desired. For example, the drying temperature can be 40° C. to 110° C. and the drying time can be 10 to 60 minutes. Exemplary preparation methods of the photoresist film are provided in the Example section below.

### EXAMPLES

### Synthesis of Polymeric Binder

### Raw Materials

S-1: styrene, CAS No.: 100-42-5.
S-2: methyl methacrylate, CAS No.: 80-62-6.
S-3: benzyl methacrylate, CAS No.: 2495-37-6.
S-4: butyl methacrylate, CAS No.: 97-88-1.
S-5: butyl acrylate, CAS No.: 141-32-2.
S-6: methacrylic acid, CAS No.: 79-41-4.
S-7: glycidyl methacrylate, CAS No.: 106-91-2.

### Synthesis Examples

According to the proportions shown in Table 1, styrene, methyl methacrylate, benzyl methacrylate, butyl methacrylate, butyl acrylate, methacrylic acid were added dropwise into a 2 L flask containing 41 parts by weight of methyl ethyl ketone (MEK) at 90° C. for 5 hr. Simultaneously, a solution of azobisisobutyronitrile (AIBN) in MEK (1.3 parts by weight in 25.7 parts by weight) was added dropwise to the mixture at 90° C. in a duration of 7 hour. After that, the mixture was then heated to 110° C. with stirring for 2-5 hours. After the reaction was completed, the mixture was quenched by methanol and cooled down to room temperature.

Then, if applicable, glycidyl methacrylate, hymono-methyl ether hydroquinone (MEHQ) and tetrabutylammonium bromide (TBAB) were added according to the proportions shown in Table 1 to a separate flask with 2.1 parts by weight of MEK to form a solution. The solution was then added dropwise to the mixture above while stirred at 65° C.-75° C. in a duration of 1 hour. Subsequently, the mixture was heated at a constant temperature of 65° C.-75° C. for 8-14 hours to allow for reaction.

After the reaction was completed, the mixture was cooled down to room temperature to obtain respective polymeric binder A-1 to A-8. The solid content of the polymeric binder is 58 wt %. The weight average molecular weight (Mw) of the polymeric binder is shown in Table 1.

TABLE 1

| | | Polymeric binder | | | | | | | |
|---|---|---|---|---|---|---|---|---|---|
| | | A-1 | A-2 | A-3 | A-4 | A-5 | A-6 | A-7 | A-8 |
| S-1 | (parts by weight) | 25 | 25 | 10 | 10 | 25 | 10 | 25 | 25 |
| S-2 | (parts by weight) | 22 | 22 | 29 | 29 | 22 | 29 | 22 | 22 |
| S-3 | (parts by weight) | 10 | 10 | 10 | 10 | 10 | 10 | 10 | 10 |
| S-4 | (parts by weight) | 4 | 4 | 10 | 10 | 4 | 10 | 4 | 4 |
| S-5 | (parts by weight) | 14 | 14 | 21 | 21 | 14 | 21 | 14 | 14 |
| S-6 | (parts by weight) | 25 | 25 | 20 | 20 | 25 | 20 | 25 | 25 |
| S-7 | (parts by weight) | 2 | 8 | 1 | 2 | | | 2 | 2 |
| MEHQ | (ppm of polymeric binder solution) | 25 | 25 | 25 | 25 | | | 200 | 300 |
| TBAB | (ppm of polymeric binder solution) | 4,000 | 4,000 | 4,000 | 4,000 | | | 4,000 | 4,000 |
| Mw | (g/mol) | 37,000 | 39,000 | 74,000 | 78,000 | 37,000 | 77000 | 39,000 | 39,000 |

### Preparation of Photosensitive Composition and Photoresist Film

### Raw Materials

### (A) Polymeric Binder

A-1 to A-8: obtained from the Synthesis Examples, with a solid content of 58 wt %

### (B) Polymerizable Compound

B-1: ethoxylated-3-trimethylolpropane triacrylate, CAS No.: 28961-43-5.
B-2: tripropylene glycol diacrylate, CAS No.: 42978-66-5
B-3: ethoxylated bisphenol A diacrylate, CAS No.: 64401 Feb. 1

### (C) Photoinitiator

C-1:2,2′-bis(2-chlorophenyl)-4,4′,5,5′-tetraphenylbiimidazole, CAS No.: 6143-80-2

### Other Components

D-1: adhesion modifier, 5-chlorobenzotriazole, CAS No.: 94-97-3
D-2: adhesion modifier, benzotriazole-5-carboxylic acid, CAS No.: 23814 Dec. 2
E-1: inhibitor, 4-tert-butylcatechol, CAS No.: 98-29-3
F-1: Leuco crystal violet, CAS No.: 603-48-5
G-1: n-phenylglycine, CAS No.: 103-01-5
H-1: solvent, methanol, CAS No.: 67-56-1
H-2: solvent, methyl ethyl ketone, CAS No.: 78-93-3

### Preparation Examples

According to the components and proportions shown in Table 2, the components were mixed to provide respective photosensitive composition. The photosensitive composition was then casted onto a polyethylene terephthalate (PET) support film with a thickness of 19 μm, followed by drying in oven (60° C. to 95° C.) for 36 minutes to provide the 280 μm photoresist films of Examples E1-E5, Comparative Examples CE1-CE2 and Reference Examples RE1-RE2.

TABLE 2

| Unit: | | | | | | | | | |
|---|---|---|---|---|---|---|---|---|---|
| parts by | | | | | | | | | |
| weight | E1 | E2 | E3 | E4 | E5 | CE1 | CE2 | RE1 | RE2 |
| A-1 | 250 | | | | | | | | |
| A-2 | | 250 | | | | | | | |
| A-3 | | | 250 | | 250 | | | | |
| A-4 | | | | 250 | | | | | |
| A-5 | | | | | | 250 | | | |
| A-6 | | | | | | | 250 | | |
| A-7 | | | | | | | | 250 | |
| A-8 | | | | | | | | | 250 |
| B-1 | 55 | 55 | 55 | 55 | 48 | 55 | 48 | 55 | 55 |
| B-2 | 14 | 14 | 14 | 14 | 13 | 14 | 13 | 14 | 14 |
| B-3 | | | | | 8 | | 8 | | |
| C-1 | 3.8 | 3.8 | 3.8 | 3.8 | 3.8 | 3.8 | 3.8 | 3.8 | 3.8 |
| D-1 | 0.022 | 0.022 | 0.022 | 0.022 | 0.022 | 0.022 | 0.022 | 0.022 | 0.022 |
| D-2 | 0.022 | 0.022 | 0.022 | 0.022 | 0.022 | 0.022 | 0.022 | 0.022 | 0.022 |
| E-1 | 0.0096 | 0.0096 | 0.0096 | 0.0096 | 0.0096 | 0.0096 | 0.0096 | 0.0096 | 0.0096 |
| F-1 | 0.48 | 0.48 | 0.48 | 0.48 | 0.48 | 0.48 | 0.48 | 0.48 | 0.48 |
| G-1 | 0.033 | 0.033 | 0.033 | 0.033 | 0.033 | 0.033 | 0.033 | 0.033 | 0.033 |
| H-1 | 19 | 19 | 19 | 19 | 19 | 19 | 19 | 19 | 19 |
| H-2 | 33 | 33 | 33 | 33 | 33 | 33 | 33 | 33 | 33 |

### Evaluation 1-Stripping Residue and Footing

The photoresist films of Examples E1-E5 and Comparative Examples CE1-CE2 were tested according to the following methods and the results are shown in Table 3.

### [Stripping Residue Test]

A photoresist film specimen sized 2 cm×2 cm is exposed with a light source of 405 nm and an exposure dosage of 240 mJ/cm² to prepare an exposed specimen.

A fresh stripper solution is prepared by dissolving tetramethylammonium hydroxide (TMAH) at a concentration of 2.5% in dimethyl sulfoxide (DMSO) to provide a 150 ml solution, followed by stirring, heating to 68° C. and keeping at 68° C. The fresh stripper solution is labelled as “level 0”.

The exposed specimen is soaked in the fresh stripper solution for 84 minutes to allow for stripping. After stripping, the specimen is removed from the used stripper solution, sonicated in pure water for 1 minute, and air-dried. The dried specimen is then inspected under a fluorescence optical microscope for stripping residue, while the used stripper solution is further used to prepare aged stripper solutions.

4 aged stripper solutions are prepared by dissolving 12.2 g, 17.4 g, 22.6 g and 27.8 g of unexposed photoresist film, respectively, in the used stripper solution. The 4 aged stripper solutions are labelled as “level 1”, “level 2”, “level 3” and “level 4”, respectively.

4 other exposed specimens are prepared in the same manner described above and soaked in the 4 aged stripper solutions with “level 1”, “level 2”, “level 3” and “level 4”, respectively, for 84 minutes to allow for stripping. After stripping, each of the specimens is removed from each of the aged stripper solutions, sonicated in pure water for 1 minute, and air-dried. The dried specimens are also inspected under a fluorescence optical microscope for stripping residue.

As the amount of photoresist film treated in a same stripping solutions increases, the stripping capability of the stripping solution decays, i.e. more likely to result in stripping residue, and the stripping solution becomes “more aged”. The objective of this test is to study if the photoresist film can be sufficiently stripped in stripper solutions with different stripping capability, with “level 0” representing “no aged” and “level 4” representing as the most aged stripper solution.

The highest level observed without stripping residue is recorded for the Examples and Comparative Example. For example, if stripping residue can still be inspected under a test at “level 3” but not at “level 2”, the result is recorded as “level 2”. As shown in Table 3, compared to Comparative Examples CE1-CE2, the photoresist films of Examples E1-E5 have good performance in a more aged stripper solution of level 3 with no residue under inspection. It means the photoresist films of Examples E1-E5 can still be stripped by using a relatively aged stripper solution while the photoresist film of Comparative Examples CE1-CE2 can only be stripped in a relatively fresh stripper solution as level 2. The photoresist films of Examples E1-E5 allow reuse of stripper solution for more times. This decreases the frequency to replace the stripper solution, enhance process efficiency, and can be less harmful to the environment.

### [Footing Measurement]

A photoresist film specimen sized 42 cm×30 cm is attached to a 20.3 cm wafer. Then, the photoresist film specimen is exposed and developed to form a predetermined pattern with a via of 160 μm in diameter, wherein the light source for exposure has a wavelength of 405 nm and the exposure dosage is 240 mJ/cm².

The patterned specimen is cut along with the wafer through the via using a wafer cutter. The cross section is then observed under a scanning electron microscope at a magnification of 550×. The term “footing” refers to the portion at the bottom of the photoresist film exceeding the predetermined pattern. With the aid of the software “JEOL SEM operation”, footing is evaluated for the Examples and Comparative example. A higher value in the result indicates a longer footing.

TABLE 3

| | E1 | E2 | E3 | E4 | E5 | CE1 | CE2 |
|---|---|---|---|---|---|---|---|
| Stripping residue | level 3 | level 3 | level 3 | level 3 | level 3 | level 2 | Level 2 |
| Footing | 9.4 | 7.7 | 7.0 | 6.4 | 6.2 | 11.6 | 8.1 |

As shown in Table 3, the photoresist films of Examples E1-E4 of the present disclosure have better performance in terms of stripping residue and footing compared to that of the Comparative Examples CE1-CE2, whose polymeric binder does not comprise the first structure unit of the present disclosure. This shows that the first structure unit is critical for the achievement of the inventive effects, i.e., reducing stripping residue and footing.

### Evaluation 2-Photosensitivity

The photoresist films of Examples E1-E5 and Reference Examples RE1-RE2 were tested according to the following methods and the results are shown in Table 4.

### [Photosensitivity Test]

The photosensitivity test is performed using a Stouffer 21-step exposure ruler. In the photosensitivity test, the position of the exposure ruler relative to the photoresist film is varied in step, and exposure is performed at each step number until the photoresist film is patternable. The photosensitivity of the photoresist film can be evaluated based on the step number, where a higher step number indicates a higher photosensitivity. Herein, the step number is converted to exposure dosage required for the photoresist film to form pattern. For example, a step number of 10 corresponds to an exposure dosage of 240 mJ/cm². The exposure dosage is recorded for the Examples and Reference Examples.

TABLE 4

| | E1 | E2 | E3 | E4 | E5 | RE1 | RE2 |
|---|---|---|---|---|---|---|---|
| Photosensitivity: | 240 | 240 | 240 | 240 | 240 | 485 | 690 |
| exposure dosage | | | | | | | |
| (mJ/cm²) | | | | | | | |

As shown in Table 4, the photoresist films of Examples E1-E5 of the present disclosure only require an exposure dosage of 240 mJ/cm² to form desirable pattern. In contrast, the photoresist films of Reference Examples RE1-RE2, whose polymeric binders are comprised in solutions comprising higher amounts of inhibitor (such as MEHQ), require comparably higher exposure dosages, which means it takes longer exposure time for the photoresist films of the Reference Examples to be patterned under the same exposure conditions. It is also notable that the required exposure dosage increases as the amount of inhibitor increases. Therefore, in embodiments where shorter exposure time is desired, the amount of the inhibitor used with the polymeric binder should not be too high and is preferably 300 ppm or less relative to 100 parts by weight of the polymeric binder.

While some embodiments are provided in the specification, they are only illustrative of the present disclosure and are not intended to limit the protection scope of the present disclosure. Persons skilled in the art may proceed with a variety of modifications based on the disclosure as described without departing from the principle thereof. The protection scope of the present disclosure is as defined in the following claims.

What is claimed is:

1. A photoresist film, which is formed from a photosensitive composition comprising:
(A) a polymeric binder, which comprises a first structural unit derived from a (meth)acrylate compound with an epoxy group;
(B) a polymerizable compound; and
(C) a photoinitiator.

2. The photoresist film of claim 1, wherein the (meth)acrylate compound with an epoxy group is selected from the group consisting of glycidyl(meth)acrylate, 2-methylglycidyl(meth)acrylate, epoxybutyl(meth)acrylate, epoxypentyl(meth)acrylate, epoxyhexyl(meth)acrylate, epoxyheptyl(meth)acrylate, epoxycyclohexylmethyl(meth)acrylate, gastrodigenin epoxy (meth)acrylate, tyrosol epoxy (meth)acrylate, and combinations thereof.

3. The photoresist film of claim 1, wherein the polymeric binder (A) further comprises a second structural unit derived from the group consisting of a (meth)acrylate compound without an epoxy group, a (meth)acrylic acid compound, an aromatic vinyl compound, a maleate compound, a linear aliphatic vinyl compound, a cycloaliphatic vinyl compound, and combinations thereof.

4. The photoresist film of claim 3, wherein the (meth)acrylate compound without an epoxy group is selected from the group consisting of benzyl(meth)acrylate, methyl(meth)acrylate, n-propyl(meth)acrylate, isopropyl(meth)acrylate, n-butyl(meth)acrylate, isobutyl(meth)acrylate, 2-ethylhexyl(meth)acrylate, tert-butyl(meth)acrylate, 2-hydroxyethyl(meth)acrylate, 2-hydroxypropyl(meth)acrylate, cyclohexyl(meth)acrylate, 1-methyl-cyclopentyl(meth)acrylate, 1-methyl-cyclohexyl(meth)acrylate, adamantyloxyethyl(meth)acrylate, 2-methyl-2-adamantyl(meth)acrylate, 2-ethyl-2-adamantyl(meth)acrylate, 2-butyl-2-adamantyl(meth)acrylate, furfuryl(meth)acrylate, tetrahydrofurfuryl(meth)acrylate, dimethylamino ethyl(meth)acrylate, diethylamino ethyl(meth)acrylate, 2,2,2-trifluoroethyl(meth)acrylate, 2,2, 3,3-tetrafluoropropyl, isobornyl(meth)acrylate, isobonyloxyethyl(meth)acrylate, dicyclopentanyl(meth)acrylate, dimethylaminoethyl (meth)acrylate, diethylaminoethyl(meth)acrylate, dicyclopentenyl-oxyethyl(meth)acrylate, dicyclopentanyl-oxyethyl(meth)acrylate, cyclohexyloxyethyl(meth)acrylate, dicyclopentenyloxypropyloxyethyl(meth)acrylate, and combinations thereof.

5. The photoresist film of claim 3, wherein the (meth)acrylic acid compound is selected from the group consisting of (meth)acrylic acid, α-bromo(meth)acrylic acid, α-chloro(meth)acrylic acid, β-phthalimido(meth)acrylic acid, β-styryl(meth)acrylic acid, β-furyl(meth)acrylic acid, and combinations thereof.

6. The photoresist film of claim 3, wherein the aromatic vinyl compound is selected from the group consisting of styrene, α-methyl styrene, vinyl naphthalene, 3-acetoxystyrene, 4-acetoxystyrene, vinyl toluene, and combinations thereof.

7. The photoresist film of claim 1, wherein the polymerizable compound (B) is selected from the group consisting of t-butyl(meth)acrylate, cyclohexyl(meth)acrylate, ethylene glycol di(meth)acrylate, butanediol di(meth)acrylate, hexamethylene glycol di(meth)acrylate, diethylene glycol di(meth)acrylate, tripropylene glycol di(meth)acrylate, 1,4-cyclo-hexanediol di(meth)acrylate, 2,2-dimethylolpropane di(meth)acrylate, polyethylene glycol di(meth)acrylate, polypropylene glycol di(meth)acrylate, trimethylolpropane di(meth)acrylate, glycerol di(meth)acrylate, glycerol tri(meth)acrylate, trimethylolpropane tri(meth)acrylate, ethoxylated trimethylolpropane tri(meth)acrylate, triethylene glycol di(meth)acrylate, ethoxylated bisphenol A di(meth)acrylate, propoxylated propylene glycol mono(meth)acrylate, propoxylated propylene glycol di(meth)acrylate, pentaaerythritol tri(meth)acrylate, pentaaerythritol tetra(meth)acrylate, 2,2-bis(4-((meth)-acryloxypolyethoxy)phenyl) propane, 2,2-bis(4-((meth)acryloxypolypropoxy)phenyl) propane, 2,2-bis(4-((meth)acryloxypolybutoxy)phenyl) propane, 2,2-bis(4-((meth)acryloxy-polyethoxypolypropoxy)phenyl) propane, and combinations thereof.

8. The photoresist film of claim 1, wherein the photoinitiator (C) is selected from the group consisting of benzophenone, bis-4,4′-dimethylaminobenzo-phenone, bis-4,4′-diethyl-aminobenzo-phenone, 2-benzyl-2-dimethylamino-1-(4-morpholino-phenyl)-1-butanone, 2-methyl-1-[4-(methylthio)phenyl]-2-morpholino-1-propanone, 9,10-anthroquinones, 1,4-naphthquinones, phenanthrene quinones, N-Phenylglycine, benzoin, benzyl dimethyl ketal, 2,2′-bis(2-chlorophenyl)-4,4′,5,5′-tetraphenylbiimidazole, 2,2′,5-tris(o-chlorophenyl)-4-(3,4-di-methoxyphenyl)-4′,5′-diphenyl-1,1′-biimidazole, 2,2′4,4′-tetra(o-chloro-phenyl)-5,5′-bis(3,4-dimethoxyphenyl)-1,1′-biimidazole, 2,2′-bis(o-chloro-phenyl)-4,4′,5,5′-tetra(m-methoxyphenyl)-1,l′-biimidazole, and 2,2′-bis(2-ethoxyphenyl)-4,4′,5,5′-tetraphenyl-1,1′-biimidazole, 9-phenylacridine, 1,7-(9,9′-acridinyl) heptane, and combinations thereof.

9. The photoresist film of claim 1, wherein the photosensitive composition further comprises an additive selected from the group consisting of a photosensitizer, an adhesion modifier, an inhibitor, a light absorber, a dye, a pigment, a surfactant, an antioxidant, a solvent, and combinations thereof.

10. The photoresist film of claim 9, wherein the polymeric binder (A) is comprised in a solution comprising an inhibitor, and the amount of the inhibitor is 300 ppm or less relative to 100 parts by weight of the polymeric binder (A).

11. The photoresist film of claim 10, wherein the inhibitor comprises hydroquinone, methylhydroquinone, tert-butylhydroquinone, 2,5-di-tert-butylhydroquinone, 2,5-bis(1,1-dimethylbutyl) hydroquinone, 2,5-bis(1,1,3,3-tetramethylbutyl) hydroquinone, resorcin, catechol, 4-tert-butylcatechol, hymono-methyl ether hydroquinone (MEHQ), pyrogallol, butylated hydroxytoluene, 2-naphthol, or a combination thereof.

12. The photoresist film of claim 1, wherein the photoresist film has a thickness ranging from 1 μm to 600 μm.
